(19) United States
(12) Patent Application Publication
(10) Pub. No.: US 2022/0192051 A1
(43) Pub. Date: Jun. 16, 2022

(54) FAN MODULE

(71) Applicant: PEGATRON CORPORATION, TAIPEI CITY (TW)

(72) Inventor: Chih Chung Ho, Taipei City (TW)

(73) Assignee: PEGATRON CORPORATION, TAIPEI CITY (TW)

(21) Appl. No.: 17/496,619

(22) Filed: Oct. 7, 2021

(30) Foreign Application Priority Data
Dec. 15, 2020 (TW) 109216577

(51) Int. Cl. H05K 7/20

(52) U.S. Cl. CPC H05K 7/20172; H05K 7/20727

(57) ABSTRACT

A fan module including a casing and multiple fans is provided. The casing includes a frame having multiple accommodation slots, a hinge element, and a cover. The cover is pivotally connected to an outlet side of the frame through the hinge element to rotate around the frame for exposing or covering at least one of the accommodation slots. The fans are disposed in the accommodation slots. When at least one of the fans is taken out of the casing and the rest of the fans are still operating, the cover covers at least one of the accommodation slots to avoid airflow leakage.

### CROSS-REFERENCE TO RELATED APPLICATION

This application claims the priority benefit of Taiwan application serial no. 109216577, filed on Dec. 15, 2020. The entirety of the above-mentioned patent application is hereby incorporated by reference herein and made a part of this specification.

### BACKGROUND

### Technical Field

The disclosure relates to a fan module, and more particularly to a fan module adapted for a server.

### Description of Related Art

In such an era of information explosion, general electronic computing devices are no longer adequate for processing a large number of data operations. At present, powerful computing devices such as servers are commonly used for processing, and cloud computing technology that various countries focus on is also a trend of development, resulting in constantly increasing usage of the servers. However, when the servers are processing huge data operations, heat generation may lead to overheat. In addition, taking the power usage of a server in a typical data center for example, a heat dissipation system usually needs to consume the same amount of the power as the server does. Therefore, as the servers are densely concentrated in a cloud data center, the data center even needs up to two times more additional heat dissipation systems than usual. In light of this, if heat dissipation problems of the cloud high-density servers are not properly handled, it will cause the server to be unstable or even unable to operate, and lead to many problems such as energy waste, unmaintained data center quality, increased data center management cost, among others. Especially when a fan needs to be repaired or replaced, how to minimize the impact thereof and maintain basic heat dissipation performance is one of the major issues in the art.

### SUMMARY

The disclosure provides a fan module, which may avoid cooling airflow leakage when some of fans are repaired or replaced.

The fan module of the disclosure includes a casing and multiple fans. The casing includes a frame having multiple accommodation slots, a hinge element, and a cover. The cover is pivoted around an outlet side of the frame by the hinge element to be open or closed for exposing or covering at least one of the accommodation slots. The fans are disposed in the respective accommodation slots. When at least one fan among the fans is taken out of the casing and the other fans among the fans are still operating, the cover covers at least one of the accommodation slots to avoid airflow leakage.

In an embodiment of the disclosure, the cover is configured to expose or cover all of the accommodation slots.

In an embodiment of the disclosure, the frame further includes an inlet side. Air inlets of the fans face the inlet side, and air outlets of the fans face the outlet side.

In an embodiment of the disclosure, the cover exposes or covers the accommodation slots close to the outlet side.

In an embodiment of the disclosure, the number of the hinge element is plural, and the hinge elements are disposed above the accommodation slots and located on the outlet side.

In an embodiment of the disclosure, the frame further comprises two opposite lateral sides, and each lateral side includes multiple diversion holes.

In an embodiment of the disclosure, the diversion holes extend in a direction from the inlet side to the outlet side.

In an embodiment of the disclosure, the casing further includes a separator disposed in the frame to define the accommodation slots.

In an embodiment of the disclosure, the separator further includes at least one snap slot, and the cover further includes at least one snap element disposed in correspondence to the at least one snap slot. The at least one snap element is snapped with the at least one snap slot when the cover covers the accommodation slot.

Based on the above, the casing of the fan module of the disclosure has the cover, which may be pivotally connected to the frame which is for accommodation the fans in order to open or close relative to the frame. In this way, the fan module may rapidly cover the accommodation slots of the frame when the fan is repaired or replaced, so as to avoid the cooling airflow leakage from above the empty accommodation slot, thereby reducing an impact of repairing or replacing the fan upon heat dissipation efficiency. Therefore, the fan module of the disclosure may greatly improve system stability of a server using the fan module.

### BRIEF DESCRIPTION OF THE DRAWINGS

FIG. 1 is a schematic view of a fan module applied to a server according to an embodiment of the disclosure.

FIG. 2 is a schematic exploded view of a fan module according to an embodiment of the disclosure.

FIG. 3 is a schematic view of at least one of accommodation slots exposed by a cover of a fan module according to an embodiment of the disclosure.

FIG. 4 is a schematic view of a fan of a fan module taken out of a casing according to an embodiment of the disclosure.

FIG. 5 is a schematic view of at least one of accommodation slots covered by a cover of a fan module according to an embodiment of the disclosure.

FIG. 6 is a schematic view of a fan module according to an embodiment of the disclosure.

### DESCRIPTION OF THE EMBODIMENTS

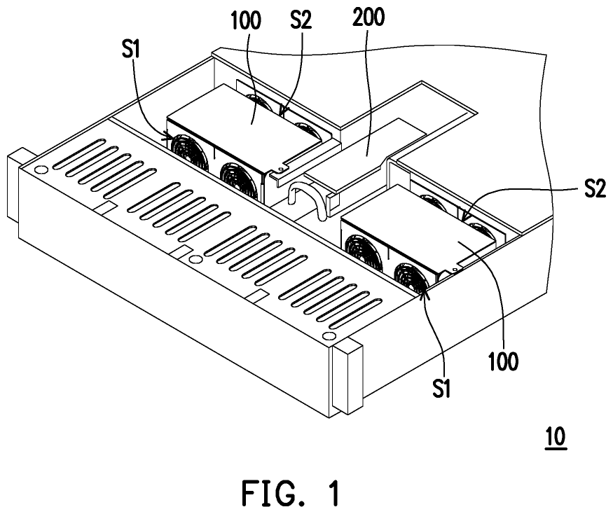

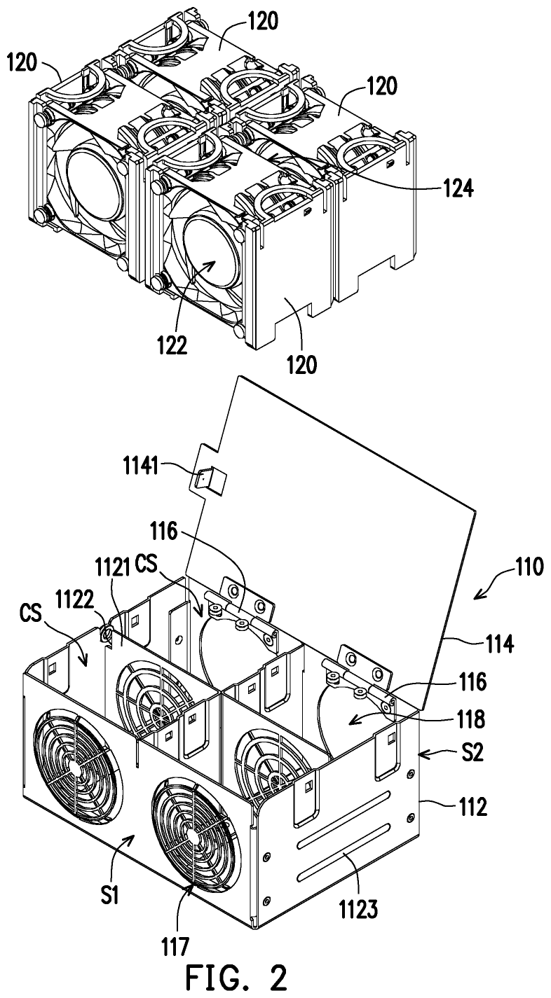

FIG. 1 is a schematic view of a fan module applied to a server according to an embodiment of the disclosure. FIG. 2 is a schematic exploded view of a fan module according to an embodiment of the disclosure. With reference to FIG. 1 and FIG. 2 together, in some embodiments, a fan module 100 may be applied to a server 10 for performing heat dissipation on heating elements (such as a motherboard and the like) in the server 10.

In some embodiments, the fan module 100 may include a casing 110 and multiple fans 120. The casing 110 may include a frame 112, a cover 114, and a hinge element 116 pivotally connecting the frame 112 and the cover 114. In some embodiments, the frame 112 may have multiple accommodation slots CS. In such configuration, the cover 114 may be pivoted around the frame 112 by the hinge element 116 to rotate relative to the frame 112 for being open or closed, thereby exposing or covering at least one of the accommodation slots CS. Specifically, in some embodiments, the casing 110 may further include a separator 1121, which may be disposed in the frame 112 to define the accommodation slots CS in the frame 112. The separator 1121 may further include a snap slot 1122, and the cover may further include a snap element 1141 corresponding to the position of the snap slot 1122. In this way, when the cover 114 covers the accommodation slots CS, the snap element 1141 of the cover 114 may be buckled with the snap slot 1122 of the separator 1121 for fixing the cover 114 on the frame 112.

In some embodiments, the frame 112 may include an inlet side S1 and an outlet side S2 opposite to each other. The fan 120 may include an air inlet 122 and an air outlet 124 opposite to each other. The air inlet 122 of the fan 120 faces the inlet side S1, and the air outlet 124 of the fan 120 faces the outlet side S2. In this way, a fan wheel of the fan 120 introduces cooling airflow from the inlet side S1 through the air inlet 122 of the fan 120, and the fan wheel is driven to cause the cooling airflow to flow out from the air outlet 124 of the fan 120 through the outlet side S2.

In this embodiment, the hinge element 116 is disposed on the outlet side S2. Specifically, the frame 112 may have a corresponding air inlet 117 disposed on the inlet side S1 and a corresponding air outlet 118 disposed on the outlet side S2, and the hinge element 116 may be disposed above the air outlet 118 of the frame 112. In this way, the cover 114 is pivoted around the outlet side S2, rotating around the frame 112 to be open or closed. In some embodiments, the number of the hinge element 116 may be plural. In some embodiments, the number of the hinge element 116 may be the same as the number of the accommodation slot CS near the outlet side S2. In this way, the hinge elements 116 may be disposed above the accommodation slots CS and located on the outlet side S2. For example, in this embodiment, the number of the hinge element 116 is two, and they are disposed on the outlet side S2, above two respective accommodation slots CS.

In this embodiment, as shown in FIG. 1, the cover 114 may expose or cover all of the accommodation slots CS. In other words, the size of the cover 114 may be approximately the same as the opening of the frame 112 so that when the cover 114 rotates around the frame 112 to be in an open state, all of the accommodation slots CS and the fans 120 disposed therein are exposed at the same time. In addition, when the cover 114 rotates around the frame 112 to be in a closed state, all of the accommodation slots CS and the fans 120 disposed therein are covered at the same time. In this way, when the fan 120 is taken out of the accommodation slot CS, the cover 114 may rotate around the frame 112 through the hinge element 116 to cover all of the accommodation slots CS, avoiding the cooling airflow from leaking from above the accommodation slots CS.

In this embodiment, there are four accommodation slots CS accommodating four fans 120. Of course, the number in this embodiment are only exemplary, and the disclosure does not limit the number of the fans 120 that may be contained in the casing 110. In this embodiment, the server 10 may include multiple fan modules 100 (shown as two in FIG. 1 but not limited thereto), and a power module 200 of the server 10 may be disposed between the two fan modules 100. However, in other embodiments, the power module 200 of the server 10 may also be disposed on one side, with the fan modules 100 all disposed on the other side. Alternatively, the server 10 may only include one fan module 100, and the frame 112 thereof may accommodate all of the fans 120. For example, the frame 112 may have eight (or more or less) accommodation slots CS to accommodate eight fans 120 required by the server 10. Of course, the number and configuration of this embodiment are only exemplary, and the disclosure does not limit the number of the fans 120 included in the fan module 100 and the element configuration inside the server 10.

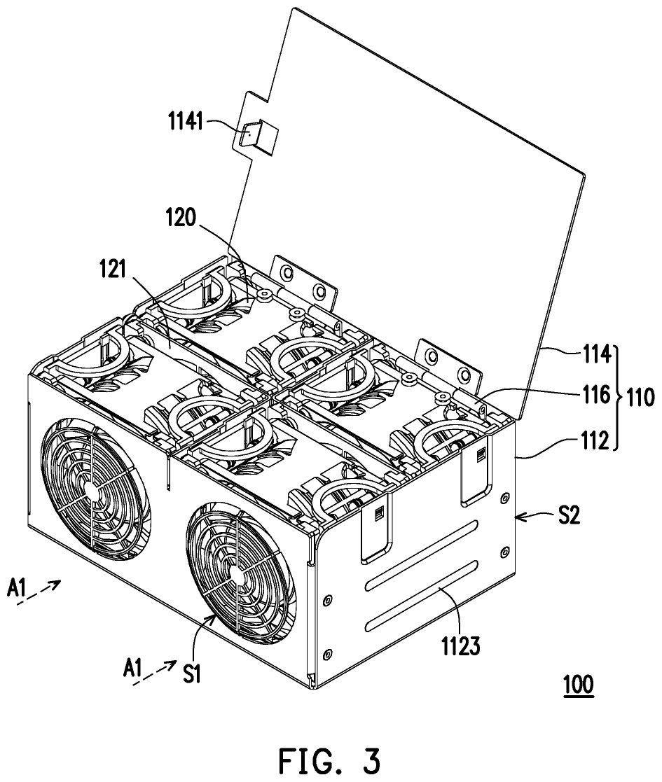

FIG. 3 shows a schematic diagram of the fan module 100 after assembly in this embodiment. With reference to FIG. 2 and FIG. 3 together, in some embodiments, the air inlet 117 and the air outlet 118 of the casing 110 may communicate with the accommodation slots CS, allowing the fan 120 to introduce cooling airflow A1 from the inlet side S1, and the fan 120 drives the cooling airflow A1 to flow out through the outlet side S2. In some embodiments, the number of the air inlets 117 and the number of the air outlets 118 are not limited as long as internal and external airflow flow smoothly without obstruction. In some embodiments, two opposite lateral sides of the frame 112 may further include multiple diversion holes 1123, which may, for example, extend in a direction from the inlet side S1 to the outlet side S2. In other words, the diversion holes 1123 may be parallel to a flow direction of the cooling airflow A1. In some cases, the fan 120 may locally generate a negative pressure zone around the fan 120 while introducing the cooling airflow A1 (exhausting). By disposing the diversion holes 1123, the airflow in the negative pressure zone may be introduced into the fan 120 to improve operating efficiency of the fan.

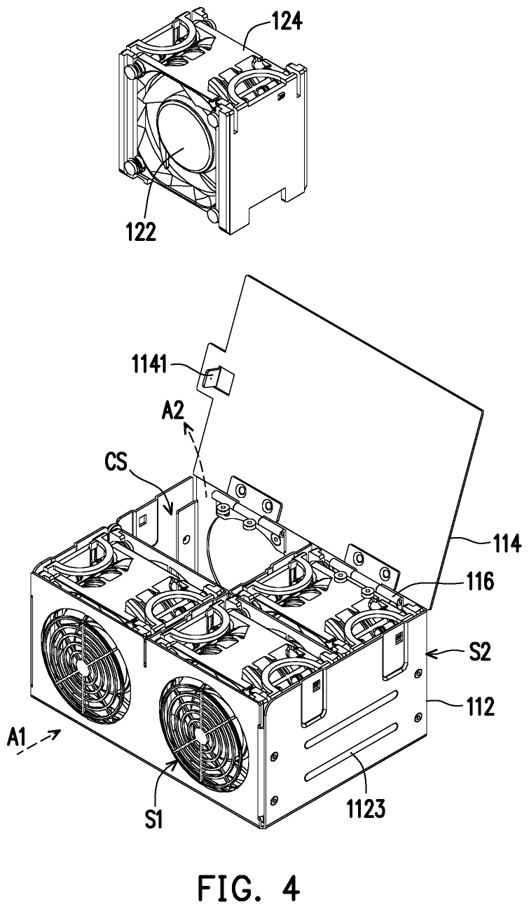

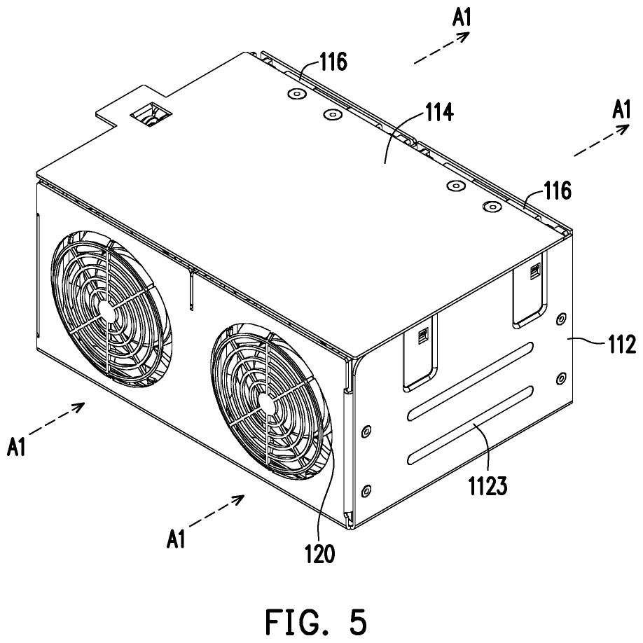

FIG. 3 is a schematic view of at least one of accommodation slots exposed by a cover of a fan module according to an embodiment of the disclosure. FIG. 4 is a schematic view of a fan of a fan module taken out of a casing according to an embodiment of the disclosure. FIG. 5 is a schematic view of at least one of accommodation slots covered by a cover of a fan module according to an embodiment of the disclosure. With reference to FIG. 3 to FIG. 5, with the above configuration, a technician who intends to repair or replace the fan 120 may perform the following steps to reduce the impact upon heat dissipation efficiency. First, the cover 114 may rotate around the frame 112 by the hinge elements 116 to be in the open state as shown in FIG. 3. Next, as shown in FIG. 4, the fan 120 to be repaired or replaced is taken out of the accommodation slot CS. In this embodiment, when the fan 120 is taken out of the accommodation slot CS, the channel that the cooling airflow A1 flows through appears an opening (i.e., the empty accommodation slot CS exposed by the cover 114). Therefore, instead of completely flowing through the outlet side S2, some cooling airflow A2 leaks out of the casing 110 from the top pf the empty accommodation slot CS, which results in a significant drop in heat dissipation efficiency. Therefore, after the fan 120 is taken out of the accommodation slot CS, operated by the technician, the cover 114 may rapidly rotate around the frame 112 by the hinge element 116 to be in the closed state as shown in FIG. 5, avoiding the cooling airflow A1 from leaking from the top of the accommodation slot CS. After the fan 120 is repaired or a new fan 120 is obtained, the technician opens the cover 114 to put the repaired fan 120 or the new fan 120 back into the empty accommodation slot CS, and closes the cover 114 to complete the step of repairing or replacing the fan 120.

In this way, with the cover 114 pivoted around the frame 112, the fan module 100 of this embodiment may rapidly cover the accommodation slots CS when the fan 120 is repaired or replaced, so as to avoid the cooling airflow A1 from leaking from the top of the accommodation slot CS, thereby reducing the impact of repairing or replacing the fan 120 upon heat dissipation efficiency. For the server 10 with high power and high heat dissipation requirements, little leakage of the cooling airflow A1 may lead to a great impact on overall performance of the server 10. Especially for the server 10 with high power, the fan module 100 of this embodiment may greatly improve system stability of the server 10.

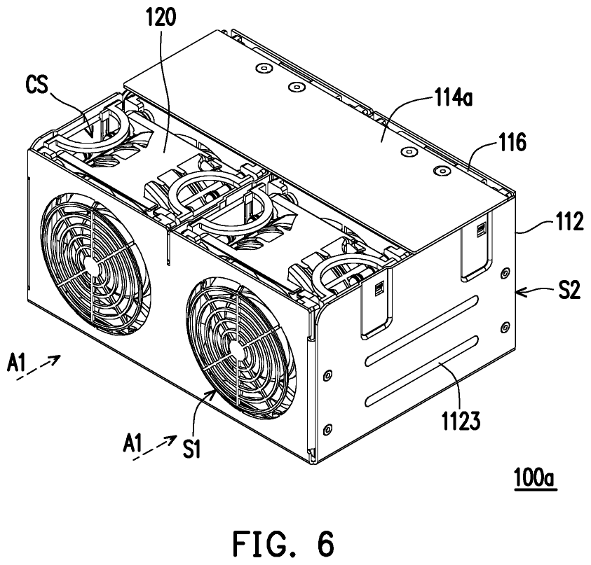

FIG. 6 is a schematic view of a fan module according to an embodiment of the disclosure. It should be noted here that a fan module 100a of this embodiment is similar to the fan module 100 of FIG. 1 and FIG. 2. Therefore, this embodiment uses the reference numerals and part of the contents of the above embodiments. The same reference numerals are used to denote the same or similar elements, and the description of the same technical contents is omitted. For the description of the omitted parts, reference may be made to the foregoing embodiments, and details are not described in this embodiment. The differences between the fan module 100a of this embodiment and the fan module 100 of FIG. 1 and FIG. 2 are explained in the following paragraphs.

With reference to FIG. 6, in some embodiments, a cover 114a is configured to cover the accommodation slots CS near the outlet side S2. Furthermore, the width of the cover 114a may be only half the width of the cover 114 of FIG. 2. Therefore, when the cover 114a is in the closed state, the cover 114a only covers the accommodation slots CS near the outlet side S2. In other words, when the cover 114a is in the closed state, the cover 114a still exposes the accommodation slots CS near the inlet side S1. Since it has a relatively greater impact upon heat dissipation efficiency when the fan 120 near the outlet side S2 is being repaired or replaced, the cover 114a may be disposed to only cover the accommodation slots CS near the outlet side S2. For example, the fan 120 near the inlet side S1 is to be repaired or replaced. When the fan 120 near the inlet side S1 is taken out, the empty accommodation slot CS may cause the cooling airflow A1 to leak upward. However, the impact upon heat dissipation efficiency of the fan module 100 is relatively small due to the fan 120 behind the empty accommodation slot CS (on the outlet side S2) which continues to introduce the cooling airflow A1 (exhausting) from the inlet side S1 and keeps driving the cooling airflow A1 to flow toward the outlet side S2. In some embodiments, in order to reduce production costs or save materials, the size of the cover 114a may be moderately reduced so that the cover 114a only covers the accommodation slots CS near the outlet side S2 and exposes the accommodation slots CS near the inlet side S1 in the closed state. Of course, this embodiment is not limited thereto. As long as the cover 114a may cover at least one of the accommodation slots CS (for example, the accommodation slot CS near the outlet side S2) in the closed state, the cover 114a may maintain the heat dissipation efficiency and improve the system stability.

In summary, the casing of the fan module of the disclosure has the cover, which may be pivoted around the frame accommodating the fans in order to be open or closed. In this way, the fan module may rapidly cover the accommodation slots of the frame when the fan is being repaired or replaced, so as to avoid the cooling airflow leakage from the top of the empty accommodation slot, thereby reducing an impact of repairing or replacing the fan upon heat dissipation efficiency. Therefore, the fan module of the disclosure may greatly improve system stability of a server using the fan module.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A fan module, comprising:
a casing, comprising a frame having a plurality of accommodation slots, a hinge element, and a cover, wherein the cover is pivoted around an outlet side of the frame by the hinge element to be open or closed for exposing or covering at least one of the accommodation slots; and
a plurality of fans, disposed in the respective accommodation slots, wherein when at least one fan among the fans is taken out of the casing and the other fans are still operating, the cover covers at least one of the accommodation slots and the other fans to avoid airflow leakage.

2. The fan module according to claim 1, wherein the cover is configured to expose or cover all of the accommodation slots.

3. The fan module according to claim 1, wherein the frame further comprises an inlet side, wherein air inlets of the fans face the inlet side, and air outlets of the fans face the outlet side.

4. The fan module according to claim 3, wherein the cover covers the accommodation slots close to the outlet side.

5. The fan module according to claim 3, wherein the number of the hinge element is plural, and the hinge elements are disposed above the respective accommodation slots and located on the outlet side.

6. The fan module according to claim 1, wherein the frame further comprises two opposite lateral sides, and each lateral side comprises a plurality of diversion holes.

7. The fan module according to claim 6, wherein the diversion holes extend in a direction from the inlet side to the outlet side.

8. The fan module according to claim 1, wherein the casing further comprises a separator disposed in the frame to define the accommodation slots.

9. The fan module according to claim 8, wherein the separator further comprises at least one snap slot, the cover further comprises at least one snap element disposed in correspondence to the at least one snap slot, and the at least one snap element is snapped with the at least one snap slot when the cover covers the accommodation slot.
